(19) United States
(12) Patent Application Publication
(10) Pub. No.: US 2016/0042968 A1
(43) Pub. Date: Feb. 11, 2016

(54) INTEGRATED OXIDE AND SI ETCH FOR 3D CELL CHANNEL MOBILITY IMPROVEMENTS

(71) Applicant: Applied Materials, Inc., Santa Clara, CA (US)

(72) Inventors: Vinod R. Purayath, Los Gatos, CA (US); Randhir Thakur, Fremont, CA (US); Nitin K. Ingle, San Jose, CA (US)

(21) Appl. No.: 14/452,328

(22) Filed: Aug. 5, 2014

(51) Int. Cl. H01L 21/311; H01L 21/3065; H01L 27/115; H01L 21/02

(52) U.S. Cl. CPC H01L 21/31116; H01L 21/02639; H01L 21/02634; H01L 21/3065; H01L 27/11565; H01L 27/11578

(57) ABSTRACT

Methods of forming single crystal channel material in a 3-d flash memory cell using only gas-phase etching techniques are described. The methods include gas-phase etching native oxide from a polysilicon layer on a conformal ONO layer. The gas-phase etch also removes native oxide from the exposed single crystal silicon substrate the bottom of a 3-d flash memory hole. The polysilicon layer is removed, also with a gas-phase etch, on the same substrate processing mainframe. Both native oxide removal and polysilicon removal use remotely excited fluorine-containing apparatuses attached to the same mainframe to facilitate performing both operations without an intervening atmospheric exposure. Epitaxial silicon is then grown from the exposed single crystal silicon to create a high mobility replacement channel.

### FIELD

Embodiments of the invention relate to methods of forming 3-d flash memory.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers or thinning lateral dimensions of features already present on the surface. Often it is desirable to have an etch process which etches one material faster than another helping e.g. a pattern transfer process proceed. Such an etch process is said to be selective of the first material. As a result of the diversity of materials, circuits and processes, etch processes have been developed that selectively remove one or more of a broad range of materials.

Dry etch processes are increasingly desirable for selectively removing material from semiconductor substrates. The desirability stems from the ability to gently remove material from miniature structures with minimal physical disturbance. Dry etch processes also allow the etch rate to be abruptly stopped by removing the gas phase reagents. Some dry-etch processes involve the exposure of a substrate to remote plasma by-products formed from one or more precursors. For example, remote plasma generation of nitrogen trifluoride in combination with ion suppression techniques enables silicon to be isotropically and selectively removed from a patterned substrate when the plasma effluents are flowed into the substrate processing region.

Methods are needed to broaden the utility of selective dry isotropic etch processes.

### SUMMARY

Methods of forming single crystal channel material in a 3-d flash memory cell using only gas-phase etching techniques are described. The methods include gas-phase etching native oxide from a polysilicon layer on a conformal ONO layer. The gas-phase etch also removes native oxide from the exposed single crystal silicon substrate the bottom of a 3-d flash memory hole. The polysilicon layer is removed, also with a gas-phase etch, on the same substrate processing mainframe. Both native oxide removal and polysilicon removal use remotely excited fluorine-containing apparatuses attached to the same mainframe to facilitate performing both operations without an intervening atmospheric exposure. Epitaxial silicon is then grown from the exposed single crystal silicon to create a high mobility replacement channel.

Embodiments include methods of forming a 3-d flash memory cell. The methods include transferring a patterned substrate into a substrate processing mainframe. The patterned substrate includes a vertical stack of alternating silicon oxide and silicon nitride slabs and a conformal ONO layer overlying the vertical stack. The conformal ONO layer includes a first silicon oxide layer, a silicon nitride layer and a second silicon oxide layer. A polysilicon layer overlies the conformal ONO layer. The methods further include transferring the patterned substrate into a first substrate processing chamber mounted on the substrate processing mainframe. The methods further include flowing a first fluorine-containing precursor into a first remote plasma region within the first substrate processing chamber while striking a plasma to form first plasma effluents from the fluorine-containing precursor. The methods further include flowing the first plasma effluents into a first substrate processing region within the first substrate processing chamber. The first substrate processing region houses the patterned substrate. The methods further include reacting the first plasma effluents with the polysilicon layer to remove a polysilicon native oxide and with an exposed single crystal silicon portion at the bottom of the vertical memory hole to remove a single crystal silicon native oxide. The methods further include transferring the patterned substrate without breaking vacuum from the first substrate processing chamber to a second substrate processing chamber mounted on the substrate processing mainframe. The methods further include flowing a second fluorine-containing precursor into a second remote plasma region within the second substrate processing chamber while striking a plasma to form second plasma effluents and flowing the second plasma effluents through a showerhead into a second substrate processing region housing the patterned substrate within the second substrate processing chamber. The methods further include reacting the second plasma effluents with the polysilicon layer to remove the polysilicon layer. The methods further include transferring the patterned substrate without breaking vacuum from the second substrate processing chamber to a third substrate processing chamber mounted on the substrate processing mainframe. The methods further include growing epitaxial silicon in the third substrate processing chamber from the exposed single crystal silicon portion to fill the memory hole. The methods further include removing the patterned substrate from the substrate processing mainframe.

Embodiments include methods of forming a 3-d flash memory cell. The methods include transferring a patterned substrate into a substrate processing mainframe. The patterned substrate includes a vertical stack of alternating silicon oxide and silicon nitride slabs and a conformal ONO layer overlying the vertical stack. The conformal ONO layer includes a first silicon oxide layer, a silicon nitride layer and a second silicon oxide layer. A polysilicon layer overlies the conformal ONO layer. The methods further include transferring the patterned substrate into a first substrate processing chamber mounted on the substrate processing mainframe. The methods further include gas-phase etching the polysilicon layer to remove a polysilicon native oxide. The methods further include gas-phase etching an exposed single crystal silicon portion at the bottom of the vertical memory hole to remove a single crystal silicon native oxide. The methods further include transferring the patterned substrate from the first substrate processing chamber to a second substrate processing chamber mounted on the substrate processing mainframe. The methods further include gas-phase etching the polysilicon layer to remove the polysilicon layer. The methods further include gas-phase etching the exposed single crystal silicon portion to ensure a single crystal orientation is exposed. The methods further include transferring the patterned substrate from the second substrate processing chamber to a third substrate processing chamber mounted on the substrate processing mainframe. The methods further include growing epitaxial silicon in the third substrate processing chamber from the exposed single crystal silicon portion to fill the memory hole. The methods further include removing the patterned substrate from the substrate processing mainframe. The patterned substrate is not exposed to atmosphere between transferring the patterned substrate into the substrate processing mainframe and removing the patterned substrate from the substrate processing mainframe.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### DESCRIPTION OF THE DRAWINGS

A further understanding of the nature and advantages of the embodiments may be realized by reference to the remaining portions of the specification and the drawings.

FIGS. 1A, 1B and 1C are cross-sectional views of a patterned substrate during an integrated etch process according to embodiments.

FIG. 2 is a flow chart of an integrated etch process according to embodiments.

FIG. 3A shows a schematic cross-sectional view of a substrate processing chamber according to embodiments.

FIG. 3B shows a schematic cross-sectional view of a portion of a substrate processing chamber according to embodiments.

FIG. 3C shows a bottom plan view of a showerhead according to embodiments.

FIG. 4 shows a top plan view of an exemplary substrate processing system according to embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Methods of forming single crystal channel material in a 3-d flash memory cell using only gas-phase etching techniques are described. The methods include gas-phase etching native oxide from a polysilicon layer on a conformal ONO layer. The gas-phase etch also removes native oxide from the exposed single crystal silicon substrate the bottom of a 3-d flash memory hole. The polysilicon layer is removed, also with a gas-phase etch, on the same substrate processing mainframe. Both native oxide removal and polysilicon removal use remotely excited fluorine-containing apparatuses attached to the same mainframe to facilitate performing both operations without an intervening atmospheric exposure. Epitaxial silicon is then grown from the exposed single crystal silicon to create a high mobility replacement channel.

Recently-developed gas-phase remote etch processes have been designed, in part, to remove the need to expose delicate surface patterns to liquid etchants. Liquid etchants are increasingly responsible for collapsing delicate surface patterns as linewidths are reduced. Further improvements in yields, performance and cost reduction are enabled by the methods presented herein. The methods involve performing several operations in the same substrate processing mainframe with multiple substrate processing chambers attached, generally around the perimeter of the mainframe. All semiconductor process chambers may be under vacuum aside from the process gases periodically introduced to treat a substrate. Prior art liquid etch processes are not candidates for such integration and so new process flows are now possible.

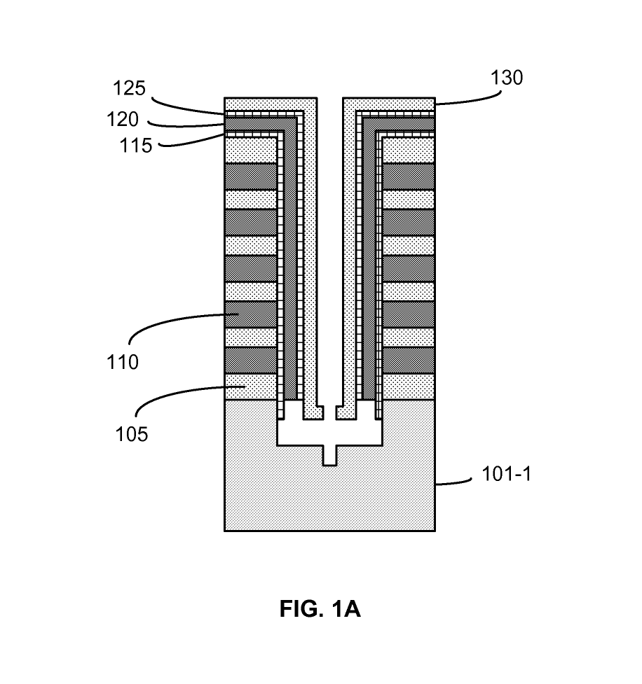

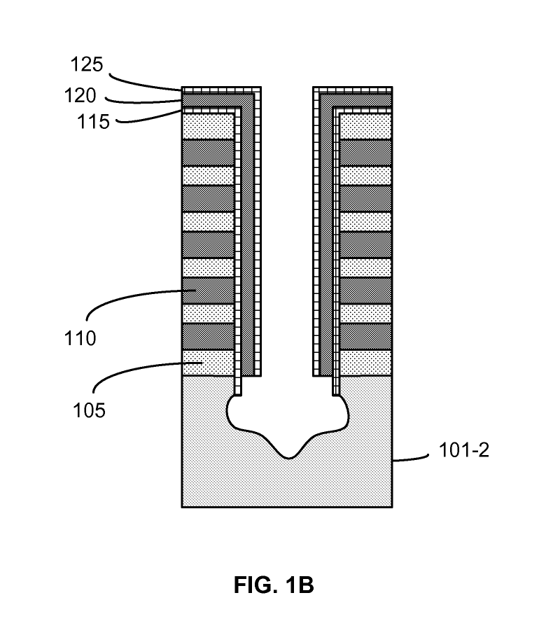

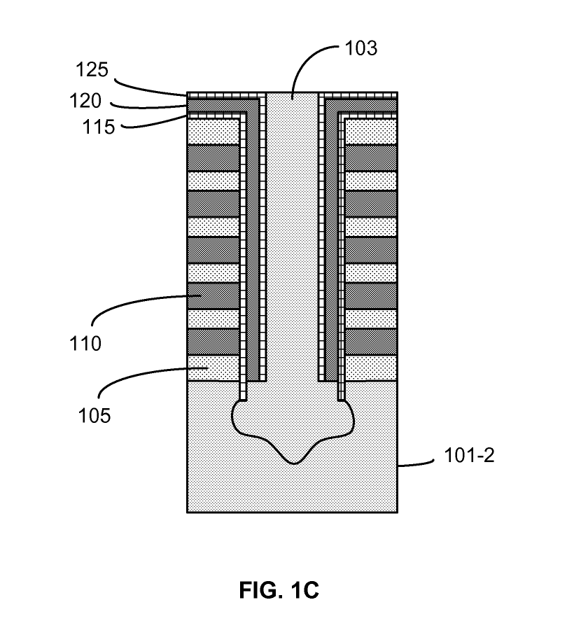

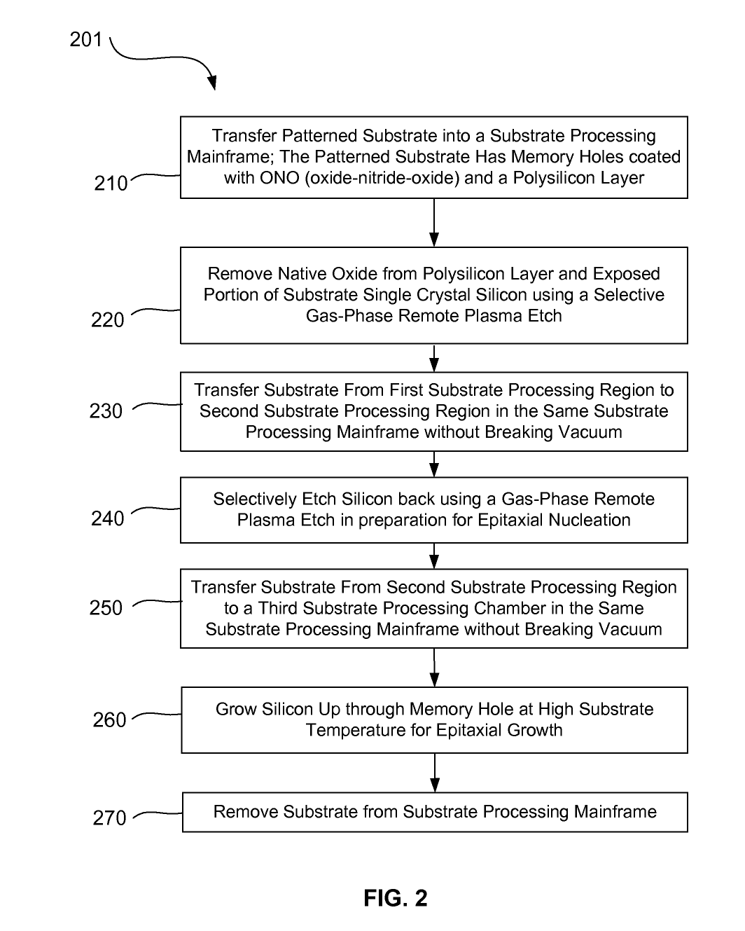

In order to better understand and appreciate embodiments of the invention, reference is now made to FIGS. 1A, 1B and 1C which are cross-sectional views of a 3-d flash memory cell during a method 201 (see FIG. 2) of forming the 3-d flash memory cells according to embodiments. In one example, a flash memory cell on patterned substrate 101-1 comprises alternatively stacked silicon oxide 105 and silicon nitride 110. The silicon nitride is sacrificial and is intended for replacement with a conductor before the device is completed. The stack of silicon oxide 105 and silicon nitride 110 is partially covered with a conformal ONO layer. The ONO layer includes a silicon oxide layer 115 (often referred to as IPD or interpoly dielectric), a silicon nitride layer 120 (which serves as the charge trap layer) and a silicon oxide layer 125 (the gate dielectric). The ONO layer is further partially covered with a polysilicon layer 130 which will be replaced to form the channel silicon. “Top” and “Up” will be used herein to describe portions/directions perpendicularly distal from the substrate plane and further away from the center of mass of the substrate in the perpendicular direction. “Vertical” will be used to describe items aligned in the “Up” direction towards the “Top”. Other similar terms may be used whose meanings will now be clear.

The ONO layer comprises a vertical portion on the interior walls of a vertical memory hole. The horizontal portion on top of the stack is outside the memory hole. The vertical portion of the ONO layer may be in contact with both stacked silicon oxide 105 layers and stacked silicon nitride 110 layers in embodiments. The vertical portion of the ONO layer may be in contact with polysilicon layer 130 according to embodiments. The vertical memory hole may be circular as viewed from above. Silicon oxide layer 115 may be in contact with silicon nitride layer 120, which may be in contact with silicon oxide layer 125 in embodiments. Silicon oxide layer 115 may contact stacked silicon oxide 105 layers and stacked silicon nitride layers 110 whereas silicon oxide layer 125 may contact polysilicon layer 130 in embodiments.

The thickness of polysilicon layer 130 depicted in each of FIGS. 1A-C may less than or about 10 nm or less than or about 10 nm according to embodiments. Silicon oxide layer 115 may have a thickness less than or about 8 nm or less than 6 nm in embodiments. Silicon oxide layer 115 may comprise or consist of silicon and oxygen in embodiments. Silicon nitride 120 may have a thickness less than or about 8 nm or less than 6 nm in embodiments. Silicon nitride layer 120 may comprise or consist of silicon and nitrogen in embodiments. Silicon oxide layer 125 may have a thickness less than or about 8 nm or less than 6 nm in embodiments. Silicon oxide layer 125 may comprise or consist of silicon and oxygen in embodiments. The constrained geometries and thinness of the layers result in damage to the memory cell when liquid etchants are used, further motivating the gas-phase etching methods presented herein. Liquid etchants cannot be as completely removed and continue to etch. Liquid etchants may ultimately form and/or penetrate through pinholes and damage devices after manufacturing is complete.

Patterned substrate 101-1 as shown in FIG. 1A is delivered into a substrate processing system (e.g. a single substrate processing mainframe) having multiple substrate processing chambers affixed and evacuated prior to transfer. Patterned substrate 101-1 is transferred into a first substrate processing region within a first substrate processing chamber (operation 210) to initiate method 201 of forming a flash memory cell. A flow of nitrogen trifluoride is then introduced into a first remote plasma region where the nitrogen trifluoride is excited in a remote plasma struck within the separate plasma region in operation 220 to etch a native oxide from polysilicon layer 130 and exposed single crystal silicon of patterned substrate 101-1. A separate plasma region may be referred to as a remote plasma region herein and may be within a distinct module from the processing chamber or a compartment within the processing chamber separated from the substrate processing region by an aperture or a showerhead. In general, a fluorine-containing precursor may be flowed into the remote plasma region and the fluorine-containing precursor comprises at least one precursor selected from the group consisting of atomic fluorine, diatomic fluorine, bromine trifluoride, chlorine trifluoride, nitrogen trifluoride, hydrogen fluoride, fluorinated hydrocarbons, sulfur hexafluoride and xenon difluoride.

According to embodiments, the plasma effluents may pass through a showerhead and/or ion suppressor to reduce the electron temperature (to reduce the ion concentration) in the substrate processing region. Reduced electron temperatures as described subsequently herein have been found to increase the etch selectivity of native silicon oxide compared to other exposed materials (e.g. polysilicon or silicon). The low electron temperatures are described later in the specification (e.g. <0.5 eV). Electron temperatures do not need to be this low if a hydrogen-containing precursor, such as ammonia, is also present in the first remote plasma region during operation 220.

In embodiments, a hydrogen-containing precursor, e.g. ammonia, may be simultaneously flowed into the first remote plasma region along with the nitrogen trifluoride described previously. The hydrogen-containing precursor may be flowed into the first remote plasma region during operation 220. Generally speaking, the hydrogen-containing precursor may include one or more of atomic hydrogen, molecular hydrogen, ammonia, a hydrocarbon and an incompletely halogen-substituted hydrocarbon.

Alternatively, an unexcited precursor may be flowed directly into the first substrate processing region without first passing the unexcited precursor through any plasma prior to entering the first substrate processing region. The unexcited precursor may be excited only by the plasma effluents formed in the first remote plasma region. The unexcited precursor may be water or an alcohol (each of which contains an OH group) in embodiments. The unexcited precursor may also be NxHy (with x and y each greater than or equal to one), may be flowed directly into first substrate processing region without prior plasma excitation. For example, the unexcited precursor may be ammonia in embodiments. The presence of the unexcited precursor just described may increase silicon oxide selectivity for etch operation 220. As before, the plasma effluents may pass through a showerhead and/or ion suppressor to reduce the electron temperature (to reduce the ion concentration) in the substrate processing region prior to combination with unexcited NxHy or OH group precursor.

Formed by the various means presented above, the plasma effluents formed in the remote plasma region are then flowed into the substrate processing region and patterned substrate 101-1 is selectively etched in operation 220 of method 201. Operation 220 (and all etches described herein) may be referred to as a gas-phase etch to highlight the contrast with liquid etch processes. The plasma effluents may enter the substrate processing region through through-holes in a showerhead or another style of aperture which separates the remote plasma region from the substrate processing region. In operation 220, native silicon oxide is removed at a much higher rate than polysilicon layer 130 to expose silicon surfaces for further processing. The reactive chemical species are removed from the substrate processing region.

Operation 220 may include applying energy to the fluorine-containing precursor while in the remote plasma region to generate the plasma effluents. As would be appreciated by one of ordinary skill in the art, the plasma may include a number of charged and neutral species including radicals and ions. The plasma may be generated using known techniques (e.g., radio frequency excitations, capacitively-coupled power or inductively coupled power). In an embodiment, the energy is applied using a capacitively-coupled plasma unit. The remote plasma source power may be between about 5 watts and about 5000 watts, between about 25 watts and about 1500 watts or between about 50 watts and about 1000 watts according to embodiments. The pressure in the remote plasma region may be such that the pressure in the substrate processing region ends up between about 0.01 Torr and about 50 Torr or between about 0.1 Torr and about 5 Torr in embodiments. The capacitively-coupled plasma unit may be disposed remote from a substrate processing region of the processing chamber. For example, the capacitively-coupled plasma unit and the plasma generation region may be separated from the gas reaction region by a showerhead. All process parameters for the native silicon oxide etch operation described herein apply to all remote plasma embodiments herein unless otherwise indicated. Other plasma parameters will be described in the exemplary equipment section.

Including a hydrogen-containing precursor with the fluorine-containing precursor in the first remote plasma region creates plasma effluents which produce solid etch by-products while etching native silicon oxide. The solid etch by-products form on the surface when the patterned substrate temperature is less than 80° C., less than 70° C. or less than 60° C. in embodiments. In this case, the solid etch by-products may be removed by sublimation effected by raising the patterned substrate temperature above 80° C., 90° C. or 100° C. according to embodiments. In order to remove the desired amount, the exposure to plasma effluents followed by sublimation may be repeated an integral number of times. The exposure to plasma effluents followed by sublimation may occur at least one, two, three, or four times, in embodiments. Lower remote plasma powers have been found to be effective when using hydrogen-containing precursor in addition to the fluorine-containing precursor in the first remote plasma region. The remote plasma source power may be between about 0.5 watts and about 500 watts, between about 3 watts and about 150 watts or between about 10 watts and about 100 watts according to embodiments.

Patterned substrate 101-1 is removed from first substrate processing region and placed in a second substrate processing region within a second substrate processing chamber affixed to the same substrate processing mainframe in operation 230. An air-tight seal is maintained between the atmosphere outside the substrate processing mainframe and the interior of substrate processing mainframe during operation 240, a trait which may also be referred to as transferring “without breaking vacuum”. Avoiding atmospheric exposure prevents the formation of a native oxide like the one just removed.

A flow of nitrogen trifluoride is then introduced into a second remote plasma region inside the second substrate processing region where the nitrogen trifluoride is excited in a second remote plasma struck within the second remote plasma region. Remote plasma parameters may be the same embodiments described for operation 220 and in the exemplary equipment section. In general, a fluorine-containing precursor may be flowed into the second remote plasma region and the fluorine-containing precursor comprises at least one precursor selected from the group consisting of atomic fluorine, diatomic fluorine, bromine trifluoride, chlorine trifluoride, nitrogen trifluoride, hydrogen fluoride, fluorinated hydrocarbons, sulfur hexafluoride and xenon difluoride. Plasma effluents are formed and passed into a second substrate processing region (operation 240) now housing patterned substrate 101-1. Polysilicon 130 is removed in operation 240 to as shown in FIG. 1C to make way for a high mobility epitaxial silicon replacement channel. Operation 240 also etches some of the exposed single crystal silicon of patterned substrate 101-2. Unused process effluents are removed from the second substrate processing region.

The second remote plasma region may be devoid or essentially devoid of hydrogen to achieve high selectivity of silicon and polysilicon relative to silicon oxide and silicon nitride during operation 240. Independently or in combination with being hydrogen-free, the second remote plasma region may be devoid of oxygen, in embodiments, during operation 240, to achieve the high selectivities of polysilicon relative to silicon oxide layer 125 (as well as silicon nitride layer 120 and silicon oxide layer 115) as described herein. As before, the plasma effluents may pass through a showerhead and/or ion suppressor to reduce the electron temperature (to reduce the ion concentration) in the substrate processing region. Reduced electron temperatures as described subsequently herein have been found to increase the etch selectivity of silicon and polysilicon relative to other exposed materials.

Patterned substrate 101-2 is removed from second substrate processing region and placed in a third substrate processing region within a third substrate processing chamber affixed to the same substrate processing mainframe in operation 250 without breaking vacuum to avoid forming a native oxide. Avoiding atmospheric exposure prevents the formation of a native oxide like the one just removed.

Epitaxial silicon 103 is then grown using the exposed portion of single crystal silicon on patterned substrate 101-2 to form material for a high mobility channel as shown in FIG. 1C. Epitaxial silicon 103 may be grown by exposing patterned substrate to silane, disilane, dichlorosilane or another silicon-containing precursor at relatively high substrate temperature. The temperature of patterned substrate 101-2 may be greater than 650° C., greater than 700° C. or greater than 800° C. according to embodiments. Patterned substrate 101 is removed from the third substrate processing region and then removed from the substrate processing mainframe (operation 270). Other processes may be carried out before removing patterned substrate 101-2 from the substrate processing mainframe according to embodiments.

All plasmas described herein may further include one or more relatively inert gases such as He, N₂, Ar. The inert gas can be used to improve plasma stability or process uniformity. Argon is helpful, as an additive, to promote the formation of a stable plasma. Process uniformity is generally increased when helium is included. These additives are present in embodiments throughout this specification. Flow rates and ratios of the different gases may be used to control etch rates and etch selectivity.

In all relevant operations (e.g. 220 and 240) embodiments described herein, the fluorine-containing gas (e.g. NF₃) is supplied at a flow rate of between about 5 sccm (standard cubic centimeters per minute) and 400 sccm, He at a flow rate of between about 0 slm (standard liters per minute) and 3 slm, and N₂ at a flow rate of between about 0 slm and 3 slm. The flow rates of ammonia, the oxygen-containing precursor, the alcohol, moisture vary widely and are selected to choose a desirable etch rate and etch selectivity of the target etch material. One of ordinary skill in the art would recognize that other gases and/or flows may be used depending on a number of factors including processing chamber configuration, substrate size and geometry and layout of features being etched. In addition to the other embodiments described herein, the pressure in the remote plasma region and/or the substrate processing region during all selective etch processes may be between about 0.01 Torr and about 30 Torr or between about 1 Torr and about 5 Torr in embodiments. The remote plasma region is disposed remote from the substrate processing region. The remote plasma region is fluidly coupled to the substrate processing region and both regions may be at roughly the same pressure during processing.

The temperature of the substrate may be between about −20° C. and about 200° C. during gapfill silicon oxide selective etch and selective etch operations later in the process. The patterned substrate temperature may also be maintained at between −10° C. and about 50° C. or between about 5° C. and about 25° C. during the gas-phase etching processes disclosed herein. Performing etching operations 220 and 240 at these extraordinarily low temperatures avoids outdiffusion of boron (or another dopant) from polysilicon layer 130, if the polysilicon has been doped at this point in the process.

In embodiments, an ion suppressor (which may be the showerhead) may be used to provide radical and/or neutral species for gas-phase etching. The ion suppressor may also be referred to as an ion suppression element. In embodiments, for example, the ion suppressor is used to filter etching plasma effluents (including radical-fluorine) en route from the remote plasma region to the substrate processing region. The ion suppressor may be used to provide a reactive gas having a higher concentration of radicals than ions. Plasma effluents pass through the ion suppressor disposed between the remote plasma region and the substrate processing region. The ion suppressor functions to dramatically reduce or substantially eliminate ionic species traveling from the plasma generation region to the substrate. The ion suppressors described herein are simply one way to achieve a low electron temperature in the substrate processing region during the gas-phase etch processes described herein.

In embodiments, an electron beam is passed through the substrate processing region in a plane parallel to the substrate to reduce the electron temperature of the plasma effluents. A simpler showerhead may be used if an electron beam is applied in this manner. The electron beam may be passed as a laminar sheet disposed above the substrate in embodiments. The electron beam provides a source of neutralizing negative charge and provides a more active means for reducing the flow of positively charged ions towards the substrate and increasing the selectivity of silicon nitride in embodiments. The flow of plasma effluents and various parameters governing the operation of the electron beam may be adjusted to lower the electron temperature measured in the substrate processing region.

The electron temperature may be measured using a Langmuir probe in the substrate processing region during excitation of a plasma in the remote plasma. In embodiments, the electron temperature may be less than 0.5 eV, less than 0.45 eV, less than 0.4 eV, or less than 0.35 eV. These extremely low values for the electron temperature are enabled by the presence of the electron beam, showerhead and/or the ion suppressor. Uncharged neutral and radical species may pass through the electron beam and/or the openings in the ion suppressor to react at the substrate. Such a process using radicals and other neutral species can reduce plasma damage compared to conventional plasma etch processes that include sputtering and bombardment. Embodiments of the present invention are also advantageous over conventional wet etch processes where surface tension of liquids can cause bending and peeling of small features.

The substrate processing region may be described herein as “plasma-free” during the etch processes described herein. “Plasma-free” does not necessarily mean the region is devoid of plasma. Ionized species and free electrons created within the plasma region may travel through pores (apertures) in the partition (showerhead) at exceedingly small concentrations. The borders of the plasma in the chamber plasma region are hard to define and may encroach upon the substrate processing region through the apertures in the showerhead. Furthermore, a low intensity plasma may be created in the substrate processing region without eliminating desirable features of the etch processes described herein. All causes for a plasma having much lower intensity ion density than the chamber plasma region during the creation of the excited plasma effluents do not deviate from the scope of “plasma-free” as used herein.

The etch selectivities during the silicon oxide etches described herein (silicon oxide:polysilicon) may be greater than or about 300:1, greater than or about 500:1, greater than or about 750:1, or greater than or about 1000:1 in embodiments. For the silicon/polysilicon etching operations, the etch selectivity of silicon or polysilicon to silicon oxide or silicon nitride may be greater than or about 700:1, greater than or about 1000:1, greater than or about 2000:1, greater than or about 3000:1 or essentially infinite according to embodiments. The etch selectivity of polysilicon or silicon relative to silicon oxide should be very high to ensure the integrity of silicon oxide 125 or charge may leak from silicon nitride 120 during operation of the completed device.

Additional process parameters are disclosed in the course of describing an exemplary processing chamber and system.

### Exemplary Processing System

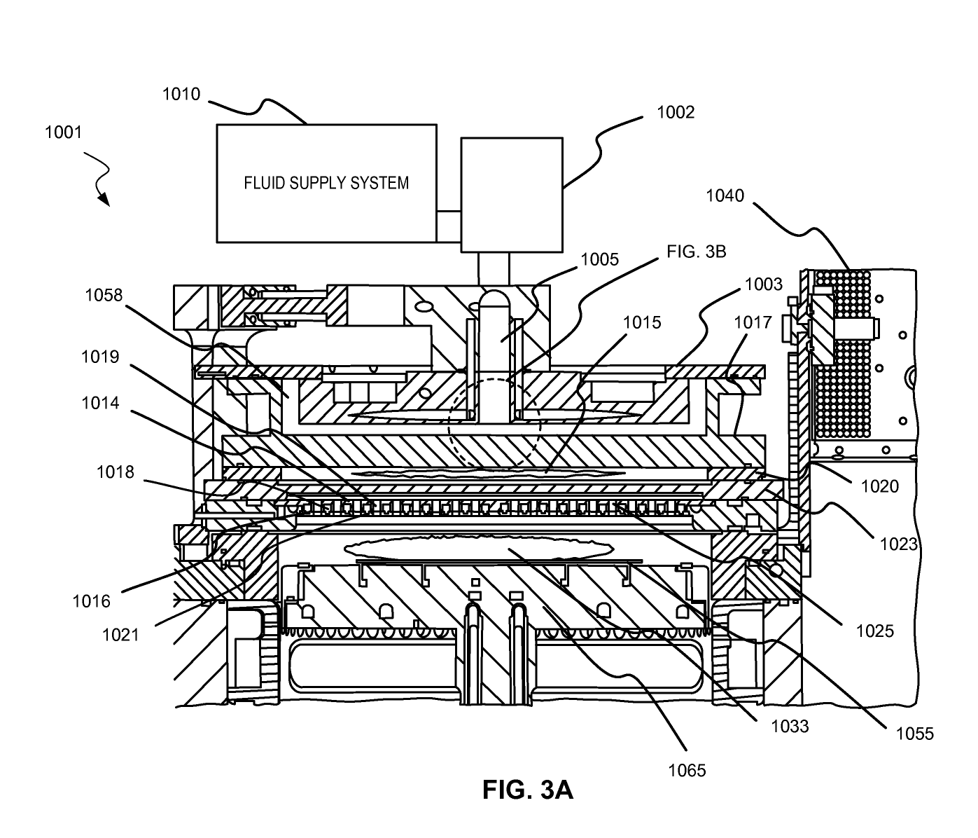

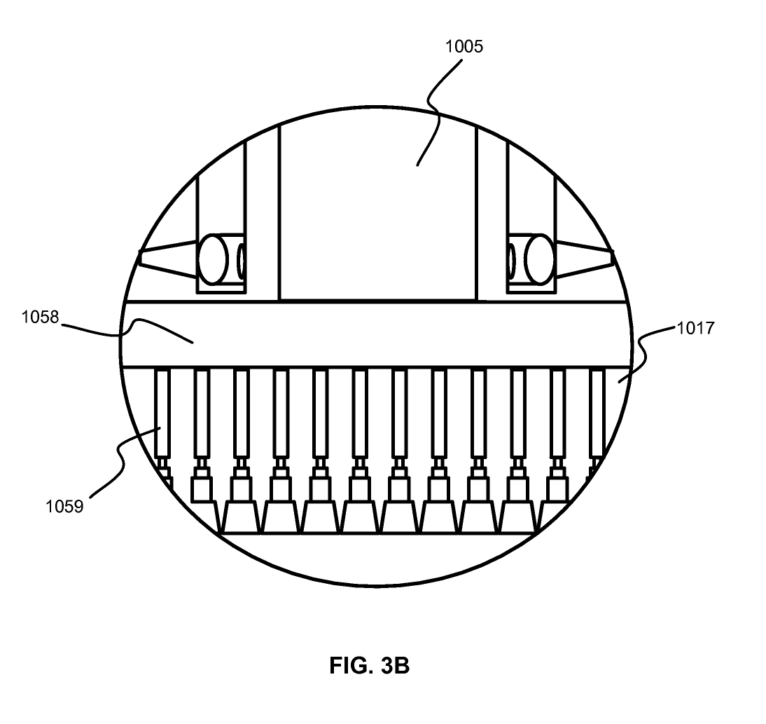

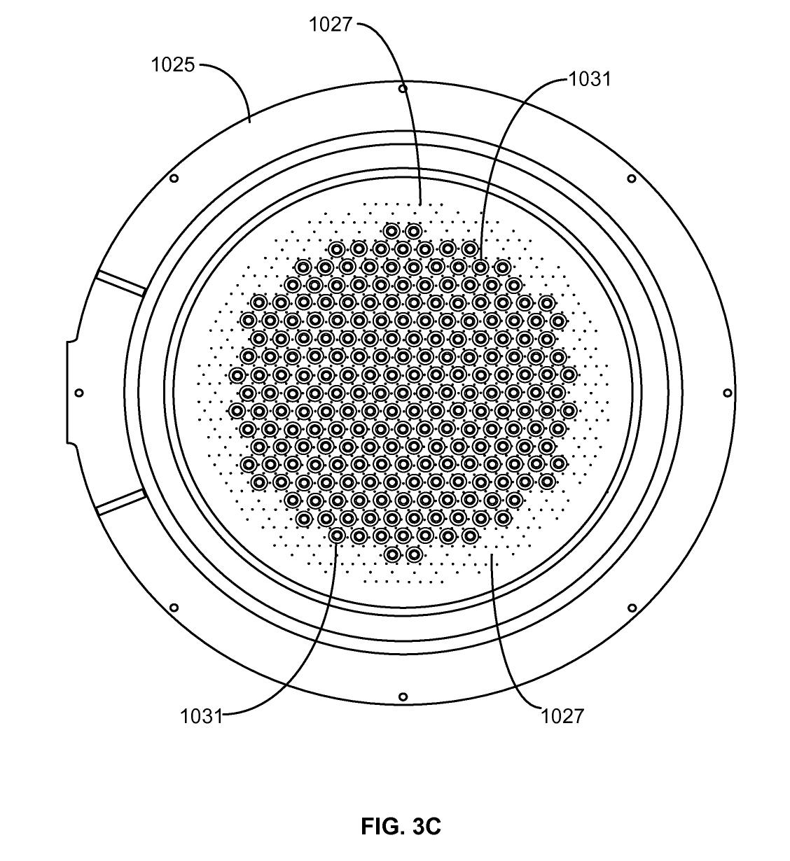

FIG. 3A shows a cross-sectional view of an exemplary substrate processing chamber 1001 with partitioned plasma generation regions within the processing chamber. During film etching, e.g., silicon oxide or polysilicon, etc., a process gas may be flowed into chamber plasma region 1015 through a gas inlet assembly 1005. A remote plasma system (RPS) 1002 may optionally be included in the system, and may process a first gas which then travels through gas inlet assembly 1005. The inlet assembly 1005 may include two or more distinct gas supply channels where the second channel (not shown) may bypass the RPS 1002, if included. Accordingly, in embodiments the precursor gases may be delivered to the processing chamber in an unexcited state. In another example, the first channel provided through the RPS may be used for the process gas and the second channel bypassing the RPS may be used for a treatment gas in embodiments. The process gas may be excited within the RPS 1002 prior to entering the chamber plasma region 1015. Accordingly, the fluorine-containing precursor as discussed above, for example, may pass through RPS 1002 or bypass the RPS unit in embodiments. Various other examples encompassed by this arrangement will be similarly understood.

A cooling plate 1003, faceplate 1017, ion suppressor 1023, showerhead 1025, and a substrate support 1065 (also known as a pedestal), having a substrate 1055 disposed thereon, are shown and may each be included according to embodiments. The pedestal 1065 may have a heat exchange channel through which a heat exchange fluid flows to control the temperature of the substrate. This configuration may allow the substrate 1055 temperature to be cooled or heated to maintain relatively low temperatures, such as between about −20° C. to about 200° C., or therebetween. The heat exchange fluid may comprise ethylene glycol and/or water. The wafer support platter of the pedestal 1065, which may comprise aluminum, ceramic, or a combination thereof, may also be resistively heated to relatively high temperatures, such as from up to or about 100° C. to above or about 1100° C., using an embedded resistive heater element. The heating element may be formed within the pedestal as one or more loops, and an outer portion of the heater element may run adjacent to a perimeter of the support platter, while an inner portion runs on the path of a concentric circle having a smaller radius. The wiring to the heater element may pass through the stem of the pedestal 1065, which may be further configured to rotate.

The faceplate 1017 may be pyramidal, conical, or of another similar structure with a narrow top portion expanding to a wide bottom portion. The faceplate 1017 may additionally be flat as shown and include a plurality of through-channels used to distribute process gases. Plasma generating gases and/or plasma excited species, depending on use of the RPS 1002, may pass through a plurality of holes, shown in FIG. 3B, in faceplate 1017 for a more uniform delivery into the chamber plasma region 1015.

Exemplary configurations may include having the gas inlet assembly 1005 open into a gas supply region 1058 partitioned from the chamber plasma region 1015 by faceplate 1017 so that the gases/species flow through the holes in the faceplate 1017 into the chamber plasma region 1015. Structural and operational features may be selected to prevent significant backflow of plasma from the chamber plasma region 1015 back into the supply region 1058, gas inlet assembly 1005, and fluid supply system 1010. The structural features may include the selection of dimensions and cross-sectional geometries of the apertures in faceplate 1017 to deactivate back-streaming plasma. The operational features may include maintaining a pressure difference between the gas supply region 1058 and chamber plasma region 1015 that maintains a unidirectional flow of plasma through the showerhead 1025. The faceplate 1017, or a conductive top portion of the chamber, and showerhead 1025 are shown with an insulating ring 1020 located between the features, which allows an AC potential to be applied to the faceplate 1017 relative to showerhead 1025 and/or ion suppressor 1023. The insulating ring 1020 may be positioned between the faceplate 1017 and the showerhead 1025 and/or ion suppressor 1023 enabling a capacitively coupled plasma (CCP) to be formed in the first plasma region. A baffle (not shown) may additionally be located in the chamber plasma region 1015, or otherwise coupled with gas inlet assembly 1005, to affect the flow of fluid into the region through gas inlet assembly 1005.

The ion suppressor 1023 may comprise a plate or other geometry that defines a plurality of apertures throughout the structure that are configured to suppress the migration of ionically-charged species out of chamber plasma region 1015 while allowing uncharged neutral or radical species to pass through the ion suppressor 1023 into an activated gas delivery region between the suppressor and the showerhead. In embodiments, the ion suppressor 1023 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 1023 may provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiO:Si etch ratios, Si:SiO etch ratios, etc.

The plurality of holes in the ion suppressor 1023 may be configured to control the passage of the activated gas, i.e., the ionic, radical, and/or neutral species, through the ion suppressor 1023. For example, the aspect ratio of the holes, or the hole diameter to length, and/or the geometry of the holes may be controlled so that the flow of ionically-charged species in the activated gas passing through the ion suppressor 1023 is reduced. The holes in the ion suppressor 1023 may include a tapered portion that faces chamber plasma region 1015, and a cylindrical portion that faces the showerhead 1025. The cylindrical portion may be shaped and dimensioned to control the flow of ionic species passing to the showerhead 1025. An adjustable electrical bias may also be applied to the ion suppressor 1023 as an additional means to control the flow of ionic species through the suppressor.

The ion suppression element 1023 may function to reduce or eliminate the amount of ionically charged species traveling from the plasma generation region to the substrate. Uncharged neutral and radical species may still pass through the openings in the ion suppressor to react with the substrate.

Showerhead 1025 in combination with ion suppressor 1023 may allow a plasma present in chamber plasma region 1015 to avoid directly exciting gases in substrate processing region 1033, while still allowing excited species to travel from chamber plasma region 1015 into substrate processing region 1033. In this way, the chamber may be configured to prevent the plasma from contacting a substrate 1055 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which silicon oxide or polysilicon etch may increase.

The processing system may further include a power supply 1040 electrically coupled with the processing chamber to provide electric power to the faceplate 1017, ion suppressor 1023, showerhead 1025, and/or pedestal 1065 to generate a plasma in the chamber plasma region 1015 or processing region 1033. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to chamber plasma region 1015. This in turn may allow development of particular plasma characteristics such that precursors may be dissociated in specific ways to enhance the etching profiles produced by these precursors.

A plasma may be ignited either in chamber plasma region 1015 above showerhead 1025 or substrate processing region 1033 below showerhead 1025. A plasma may be present in chamber plasma region 1015 to produce the radical-fluorine precursors from an inflow of the fluorine-containing precursor. An AC voltage typically in the radio frequency (RF) range may be applied between the conductive top portion of the processing chamber, such as faceplate 1017, and showerhead 1025 and/or ion suppressor 1023 to ignite a plasma in chamber plasma region 1015 during deposition. An RF power supply may generate a high RF frequency of 13.56 MHz but may also generate other frequencies alone or in combination with the 13.56 MHz frequency.

Plasma power can be of a variety of frequencies or a combination of multiple frequencies. In the exemplary processing system the plasma may be provided by RF power delivered to faceplate 1017 relative to ion suppressor 1023 and/or showerhead 1025. The RF power may be between about 10 watts and about 5000 watts, between about 100 watts and about 2000 watts, between about 200 watts and about 1500 watts, or between about 200 watts and about 1000 watts in embodiments. The RF frequency applied in the exemplary processing system may be low RF frequencies less than about 200 kHz, high RF frequencies between about 10 MHz and about 15 MHz, or microwave frequencies greater than or about 1 GHz in embodiments. The plasma power may be capacitively-coupled (CCP) or inductively-coupled (ICP) into the remote plasma region.

Chamber plasma region 1015 (top plasma in figure) may be left at low or no power when a bottom plasma in the substrate processing region 1033 is turned on to, for example, cure a film or clean the interior surfaces bordering substrate processing region 1033. A plasma in substrate processing region 1033 may be ignited by applying an AC voltage between showerhead 1025 and the pedestal 1065 or bottom of the chamber. A treatment gas (such as argon) may be introduced into substrate processing region 1033 while the plasma is present to facilitate treatment of the patterned substrate. The showerhead 1025 may also be biased at a positive DC voltage relative to the pedestal 1065 or bottom of the chamber to accelerate positively charged ions toward patterned substrate 1055. In embodiments, the local plasma in substrate processing region 1033 may be struck by applying AC power via an inductively-coupled source while applying DC power by capacitively coupled means. As indicated previously, the local plasma power may be between about 10 watts and about 500 watts, between about 20 watts and about 400 watts, between about 30 watts and about 300 watts, or between about 50 watts and about 200 watts in embodiments.

A fluid, such as a precursor, for example a fluorine-containing precursor, may be flowed into the processing region 1033 by embodiments of the showerhead described herein. Excited species derived from the process gas in chamber plasma region 1015 may travel through apertures in the ion suppressor 1023, and/or showerhead 1025 and react with an additional precursor flowing into the processing region 1033 from a separate portion of the showerhead. Alternatively, if all precursor species are being excited in chamber plasma region 1015, no additional precursors may be flowed through the separate portion of the showerhead. Little or no plasma may be present in the processing region 1033 during the remote plasma etch process. Excited derivatives of the precursors may combine in the region above the substrate and/or on the substrate to etch structures or remove species from the substrate.

Exciting the fluids in the chamber plasma region 1015 directly, or exciting the fluids in the RPS units 1002, may provide several benefits. The concentration of the excited species derived from the fluids may be increased within the processing region 1033 due to the plasma in the chamber plasma region 1015. This increase may result from the location of the plasma in the chamber plasma region 1015. The processing region 1033 may be located closer to the chamber plasma region 1015 than the remote plasma system (RPS) 1002, leaving less time for the excited species to leave excited states through collisions with other gas molecules, walls of the chamber, and surfaces of the showerhead.

The uniformity of the concentration of the excited species derived from the process gas may also be increased within the processing region 1033. This may result from the shape of the chamber plasma region 1015, which may be more similar to the shape of the processing region 1033. Excited species created in the RPS 1002 may travel greater distances to pass through apertures near the edges of the showerhead 1025 relative to species that pass through apertures near the center of the showerhead 1025. The greater distance may result in a reduced excitation of the excited species and, for example, may result in a slower growth rate near the edge of a substrate. Exciting the fluids in the chamber plasma region 1015 may mitigate this variation for the fluid flowed through RPS 1002, or alternatively bypassed around the RPS unit.

The processing gases may be excited in chamber plasma region 1015 and may be passed through the showerhead 1025 to the processing region 1033 in the excited state. While a plasma may be generated in the processing region 1033, a plasma may alternatively not be generated in the processing region. In one example, the only excitation of the processing gas or precursors may be from exciting the processing gases in chamber plasma region 1015 to react with one another in the processing region 1033. As previously discussed, this may be to protect the structures patterned on the substrate 1055.

In addition to the fluid precursors, there may be other gases introduced at varied times for varied purposes, including carrier gases to aid delivery. A treatment gas may be introduced to remove unwanted species from the chamber walls, the substrate, the deposited film and/or the film during deposition. A treatment gas may be excited in a plasma and then used to reduce or remove residual content inside the chamber. In some embodiments the treatment gas may be used without a plasma. When the treatment gas includes water vapor, the delivery may be achieved using a mass flow meter (MFM), an injection valve, or by commercially available water vapor generators. The treatment gas may be introduced to the processing region 1033, either through the RPS unit or bypassing the RPS unit, and may further be excited in the first plasma region.

FIG. 3B shows a detailed view of the features affecting the processing gas distribution through faceplate 1017. As shown in FIG. 3A and FIG. 3B, faceplate 1017, cooling plate 1003, and gas inlet assembly 1005 intersect to define a gas supply region 1058 into which process gases may be delivered from gas inlet 1005. The gases may fill the gas supply region 1058 and flow to chamber plasma region 1015 through apertures 1059 in faceplate 1017. The apertures 1059 may be configured to direct flow in a substantially unidirectional manner such that process gases may flow into processing region 1033, but may be partially or fully prevented from backflow into the gas supply region 1058 after traversing the faceplate 1017.

The gas distribution assemblies such as showerhead 1025 for use in the processing chamber section 1001 may be referred to as dual channel showerheads (DCSH) and are additionally detailed in the embodiments described in FIG. 3A as well as FIG. 3C herein. The dual channel showerhead may provide for etching processes that allow for separation of etchants outside of the processing region 1033 to provide limited interaction with chamber components and each other prior to being delivered into the processing region.

The showerhead 1025 may comprise an upper plate 1014 and a lower plate 1016. The plates may be coupled with one another to define a volume 1018 between the plates. The coupling of the plates may be so as to provide first fluid channels 1019 through the upper and lower plates, and second fluid channels 1021 through the lower plate 1016. The formed channels may be configured to provide fluid access from the volume 1018 through the lower plate 1016 via second fluid channels 1021 alone, and the first fluid channels 1019 may be fluidly isolated from the volume 1018 between the plates and the second fluid channels 1021. The volume 1018 may be fluidly accessible through a side of the gas distribution assembly 1025. Although the exemplary system of FIGS. 3A-3C includes a dual-channel showerhead, it is understood that alternative distribution assemblies may be utilized that maintain first and second precursors fluidly isolated prior to the processing region 1033. For example, a perforated plate and tubes underneath the plate may be utilized, although other configurations may operate with reduced efficiency or not provide as uniform processing as the dual-channel showerhead as described.

In the embodiment shown, showerhead 1025 may distribute via first fluid channels 1019 process gases which contain plasma effluents upon excitation by a plasma in chamber plasma region 1015. In embodiments, the process gas introduced into the RPS 1002 and/or chamber plasma region 1015 may contain fluorine, e.g., CF₄, NF₃ or XeF₂. The process gas may also include a carrier gas such as helium, argon, nitrogen (N₂), etc. Plasma effluents may include ionized or neutral derivatives of the process gas and may also be referred to herein as a radical-fluorine precursor referring to the atomic constituent of the process gas introduced.

FIG. 3C is a bottom view of a showerhead 1025 for use with a processing chamber in embodiments. Showerhead 1025 corresponds with the showerhead shown in FIG. 3A. Through-holes 1031, which show a view of first fluid channels 1019, may have a plurality of shapes and configurations to control and affect the flow of precursors through the showerhead 1025. Small holes 1027, which show a view of second fluid channels 1021, may be distributed substantially evenly over the surface of the showerhead, even amongst the through-holes 1031, which may help to provide more even mixing of the precursors as they exit the showerhead than other configurations.

The chamber plasma region 1015 or a region in an RPS may be referred to as a remote plasma region. In embodiments, the radical precursor, e.g., a radical-fluorine precursor, is created in the remote plasma region and travels into the substrate processing region where it may or may not combine with additional precursors. In embodiments, the additional precursors are excited only by the radical-fluorine precursor. Plasma power may essentially be applied only to the remote plasma region in embodiments to ensure that the radical-fluorine precursor provides the dominant excitation. Nitrogen trifluoride or another fluorine-containing precursor may be flowed into chamber plasma region 1015 at rates between about 5 sccm and about 500 sccm, between about 10 sccm and about 150 sccm, or between about 25 sccm and about 125 sccm in embodiments.

Combined flow rates of precursors into the chamber may account for 0.05% to about 20% by volume of the overall gas mixture; the remainder being carrier gases. The fluorine-containing precursor may be flowed into the remote plasma region, but the plasma effluents may have the same volumetric flow ratio in embodiments. In the case of the fluorine-containing precursor, a purge or carrier gas may be first initiated into the remote plasma region before the fluorine-containing gas to stabilize the pressure within the remote plasma region. Substrate processing region 1033 can be maintained at a variety of pressures during the flow of precursors, any carrier gases, and plasma effluents into substrate processing region 1033. The pressure may be maintained between about 0.1 mTorr and about 100 Torr, between about 1 Torr and about 20 Torr or between about 1 Torr and about 5 Torr in embodiments.

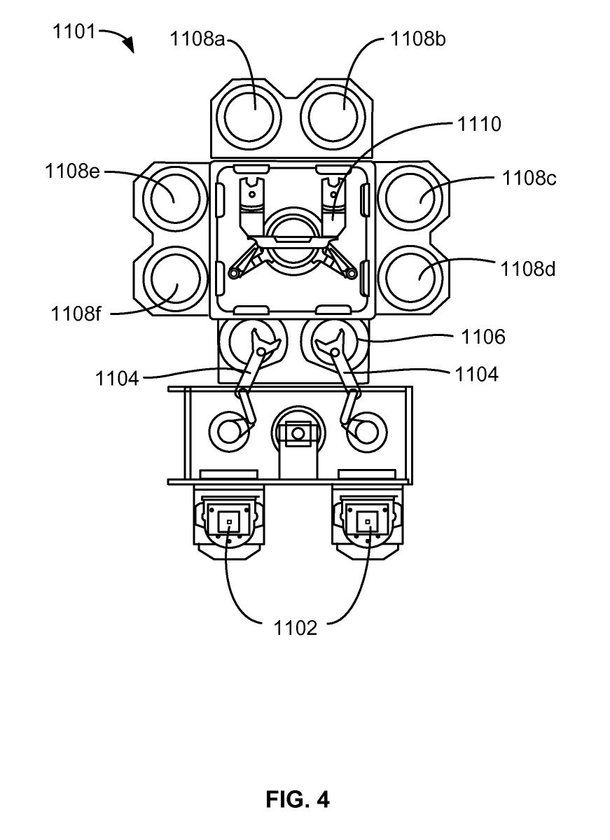

Embodiments of the deposition systems may be incorporated into larger fabrication systems for producing integrated circuit chips. FIG. 4 shows one such processing system (mainframe) 1101 of deposition, etching, baking, and curing chambers in embodiments. In the figure, a pair of front opening unified pods (load lock chambers 1102) supply substrates of a variety of sizes that are received by robotic arms 1104 and placed into a low pressure holding area 1106 before being placed into one of the substrate processing chambers 1108a-f. A second robotic arm 1110 may be used to transport the substrate wafers from the holding area 1106 to the substrate processing chambers 1108a-f and back. Each substrate processing chamber 1108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 1108a-f may be configured for depositing, annealing, curing and/or etching a film on the substrate wafer. In one configuration, chambers 1108a-b, may be configured to etch native oxide, chambers 1108c-d may be configured to etch silicon and polysilicon, and chambers 1108e-f may be configured to grow epitaxial silicon.

In the preceding description, for the purposes of explanation, numerous details have been set forth to provide an understanding of various embodiments of the present invention. It will be apparent to one skilled in the art, however, that certain embodiments may be practiced without some of these details, or with additional details.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “silicon” or “polysilicon” of the patterned substrate is predominantly Si but may include minority concentrations of other elemental constituents such as nitrogen, oxygen, hydrogen and carbon. Exposed “silicon” or “polysilicon” may consist of or consist essentially of silicon. Exposed “silicon nitride” of the patterned substrate is predominantly Si₃N₄ but may include minority concentrations of other elemental constituents such as oxygen, hydrogen and carbon. “Exposed silicon nitride” may consist essentially of or consist of silicon and nitrogen. Exposed “silicon oxide” of the patterned substrate is predominantly SiO₂ but may include minority concentrations of other elemental constituents such as nitrogen, hydrogen and carbon. In embodiments, silicon oxide films etched using the methods taught herein consist essentially of or consist of silicon and oxygen.

The term “precursor” is used to refer to any process gas which takes part in a reaction to either remove material from or deposit material onto a surface. “Plasma effluents” describe gas exiting from the chamber plasma region and entering the substrate processing region. Plasma effluents are in an “excited state” wherein at least some of the gas molecules are in vibrationally-excited, dissociated and/or ionized states. A “radical precursor” is used to describe plasma effluents (a gas in an excited state which is exiting a plasma) which participate in a reaction to either remove material from or deposit material on a surface. “Radical-fluorine” are radical precursors which contain fluorine but may contain other elemental constituents. The phrase “inert gas” refers to any gas which does not form chemical bonds when etching or being incorporated into a film. Exemplary inert gases include noble gases but may include other gases so long as no chemical bonds are formed when (typically) trace amounts are trapped in a film.

The terms “gap” and “trench” are used throughout with no implication that the etched geometry has a large horizontal aspect ratio. Viewed from above the surface, trenches may appear circular, oval, polygonal, rectangular, or a variety of other shapes. A trench may be in the shape of a moat around an island of material. The term “via” is used to refer to a low aspect ratio trench (as viewed from above) which may or may not be filled with metal to form a vertical electrical connection. As used herein, an isotropic or a conformal etch process refers to a generally uniform removal of material on a surface in the same shape as the surface, i.e., the surface of the etched layer and the pre-etch surface are generally parallel. A person having ordinary skill in the art will recognize that the etched interface likely cannot be 100% conformal and thus the term “generally” allows for acceptable tolerances.

Having disclosed several embodiments, it will be recognized by those of skill in the art that various modifications, alternative constructions, and equivalents may be used without departing from the spirit of the disclosed embodiments. Additionally, a number of well-known processes and elements have not been described to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

1. A method of forming a 3-d flash memory cell, the method comprising:
transferring a patterned substrate into a substrate processing mainframe, wherein the patterned substrate comprises a vertical stack of alternating silicon oxide and silicon nitride slabs and a conformal ONO layer overlying the vertical stack, wherein the conformal ONO layer comprises a first silicon oxide layer, a silicon nitride layer and a second silicon oxide layer, and wherein a polysilicon layer overlies the conformal ONO layer;
transferring the patterned substrate into a first substrate processing chamber mounted on the substrate processing mainframe;
flowing a first fluorine-containing precursor into a first remote plasma region within the first substrate processing chamber while striking a plasma to form first plasma effluents from the fluorine-containing precursor;
flowing the first plasma effluents into a first substrate processing region within the first substrate processing chamber; wherein the first substrate processing region houses the patterned substrate;
reacting the first plasma effluents with the polysilicon layer to remove a polysilicon native oxide and with an exposed single crystal silicon portion at the bottom of the vertical memory hole to remove a single crystal silicon native oxide;
transferring the patterned substrate without breaking vacuum from the first substrate processing chamber to a second substrate processing chamber mounted on the substrate processing mainframe;
flowing a second fluorine-containing precursor into a second remote plasma region within the second substrate processing chamber while striking a plasma to form second plasma effluents and flowing the second plasma effluents through a showerhead into a second substrate processing region housing the patterned substrate within the second substrate processing chamber;
reacting the second plasma effluents with the polysilicon layer to remove the polysilicon layer;
transferring the patterned substrate without breaking vacuum from the second substrate processing chamber to a third substrate processing chamber mounted on the substrate processing mainframe;
growing epitaxial silicon in the third substrate processing chamber from the exposed single crystal silicon portion to fill the memory hole; and
removing the patterned substrate from the substrate processing mainframe.

2. The method of claim 1, wherein the first plasma effluents are combined with an unexcited precursor not passed through any plasma prior to entering the first substrate processing region.

3. The method of claim 2, wherein the unexcited precursor comprises water, an alcohol, or NxHy where x and y are greater than or equal to one.

4. The method of claim 1, wherein reacting the first plasma effluents with the polysilicon layer further comprises sublimating solid etch by-products from the patterned substrate.

5. The method of claim 1, wherein the vertical memory hole is circular as viewed from above.

6. The method of claim 1, wherein the first fluorine-containing precursor is nitrogen trifluoride and the second fluorine-containing precursor is nitrogen trifluoride.

7. The method of claim 1, wherein reacting the second plasma effluents further comprises reacting the second plasma effluents with the exposed single crystal silicon portion to improve the epitaxial silicon grown in the third substrate processing chamber.

8. A method of forming a 3-d flash memory cell, the method comprising:
transferring a patterned substrate into a substrate processing mainframe, wherein the patterned substrate comprises a vertical stack of alternating silicon oxide and silicon nitride slabs and a conformal ONO layer overlying the vertical stack, wherein the conformal ONO layer comprises a first silicon oxide layer, a silicon nitride layer and a second silicon oxide layer, and wherein a polysilicon layer overlies the conformal ONO layer;
transferring the patterned substrate into a first substrate processing chamber mounted on the substrate processing mainframe;
gas-phase etching the polysilicon layer to remove a polysilicon native oxide;
gas-phase etching an exposed single crystal silicon portion at the bottom of the vertical memory hole to remove a single crystal silicon native oxide;
transferring the patterned substrate from the first substrate processing chamber to a second substrate processing chamber mounted on the substrate processing mainframe;
gas-phase etching the polysilicon layer to remove the polysilicon layer;
gas-phase etching the exposed single crystal silicon portion to ensure a single crystal orientation is exposed;
transferring the patterned substrate from the second substrate processing chamber to a third substrate processing chamber mounted on the substrate processing mainframe;
growing epitaxial silicon in the third substrate processing chamber from the exposed single crystal silicon portion to fill the memory hole; and
removing the patterned substrate from the substrate processing mainframe, wherein the patterned substrate is not exposed to atmosphere between transferring the patterned substrate into the substrate processing mainframe and removing the patterned substrate from the substrate processing mainframe.

9. The method of claim 8, wherein gas-phase etching the polysilicon layer comprises flowing plasma effluents into a first substrate processing region within the first substrate processing chamber, wherein the plasma effluents were generated in a remote plasma from a first fluorine-containing precursor.

10. The method of claim 9, wherein the remote plasma further comprises a hydrogen-containing precursor.

11. The method of claim 9, wherein an electron temperature in the first substrate processing region is less than 0.5 eV during gas-phase etching the polysilicon layer to remove the polysilicon native oxide.

12. The method of claim 8, wherein gas-phase etching the polysilicon layer comprises flowing plasma effluents into a second substrate processing region within the second substrate processing chamber, wherein the plasma effluents were generated from a second fluorine-containing precursor within a second remote plasma region.

13. The method of claim 12, wherein the plasma effluents are hydrogen-free.

14. The method of claim 12, wherein the plasma effluents are oxygen-free.

15. The method of claim 8, wherein the growing epitaxial silicon comprises exposing the patterned substrate to a silicon-containing precursor while the patterned substrate is maintained at 650° C. or above.
